(19) United States
(12) Patent Application Publication
(10) Pub. No.: US 2025/0069653 A1
(43) Pub. Date: Feb. 27, 2025

(54) COMPUTING-IN-MEMORY CIRCUIT AND SRAM MEMORY DEVICE

(71) Applicant: INSTITUTE OF MICROELECTRONICS, CHINESE ACADEMY OF SCIENCES, Beijing (CN)

(72) Inventors: Huaxiang YIN, Beijing (CN); Xuexiang ZHANG, Beijing (CN); Jiaxin YAO, Beijing (CN)

(21) Appl. No.: 18/947,250

(22) Filed: Nov. 14, 2024

(30) Foreign Application Priority Data
Jul. 17, 2024 (CN) 202410961825.3

(51) Int. Cl. G11C 11/419; G11C 11/418; H03K 19/20

(52) U.S. Cl. CPC G11C 11/419; G11C 11/418; H03K 19/20

(57) ABSTRACT

The computing-in-memory circuit includes: an SRAM memory cell array including at least one memory cell connected between a first bit line and a second bit line, the memory cell includes a first inverter and a second inverter cross-coupled with each other, and the first inverter and the second inverter have an asymmetric configuration with respect to each other; a control circuit configured to: receive a first input signal, a second input signal and an operation mode control signal, process the first input signal and the second input signal according to operation mode control signal, so as to obtain a processed first input signal and a processed second input signal, and apply the processed first input signal and the processed second input signal to the first bit line and the second bit line, respectively; and a readout circuit configured to read out data stored in memory cell from the memory cell.

### CROSS-REFERENCE TO RELATED APPLICATION

This application claims the priority of Chinese Patent Application No. 202410961825.3 filed on Jul. 17, 2024 in the China National Intellectual Property Administration, the content of which is incorporated herein by reference in entirety.

### TECHNICAL FIELD

The present disclosure relates to a field of an integrated circuit technology, and more specifically, to a computing-in-memory circuit and an SRAM memory device.

### BACKGROUND

As a process improvement gap between a processor and a memory widens, and a gap between a processing speed of a memory and a processing speed of a processor under a Von Neumann architecture increases continually, a problem of memory access power consumption wall is becoming increasingly prominent. On this basis, with a rapid increase in a calculation amount, a frequent data exchange has brought a challenge to a storage speed and storage power consumption of the memory. Based on this, there is a problem of a limited data computing efficiency due to a low storage speed and a high storage power consumption of the memory.

### SUMMARY

In view of the above-mentioned problems, the present disclosure provides a computing-in-memory circuit and an SRAM memory device.

According to an aspect of the present disclosure, there is provided a computing-in-memory circuit, including: an SRAM memory cell array including at least one memory cell connected between a first bit line and a second bit line, where the memory cell includes a first inverter and a second inverter cross-coupled with each other, and the first inverter and the second inverter have an asymmetric configuration with respect to each other; a control circuit configured to: receive a first input signal, a second input signal and an operation mode control signal, process the first input signal and the second input signal according to the operation mode control signal, so as to obtain a processed first input signal and a processed second input signal, and apply the processed first input signal and the processed second input signal to the first bit line and the second bit line, respectively; and a readout circuit configured to read out data stored in the memory cell from the memory cell, where the memory cell is configured to store the data according to the processed first input signal and the processed second input signal applied to the first bit line and the second bit line, and the data corresponds to a result obtained by performing a logical operation indicated by the operation mode control signal on the first input signal and the second input signal.

According to embodiments of the present disclosure, the asymmetric configuration causes the memory cell to: store data having a first data state when a level corresponding to the first data state is applied to the first bit line and a level corresponding to a second data state is applied to the second bit line, wherein the second data state is in a reverse phase with the first data state; and store data having a data state or a data state that is in a reverse phase with the data state when a level corresponding to the same data state is applied to the first bit line and the second bit line.

According to embodiments of the present disclosure, the asymmetric configuration causes the memory cell to: store data corresponding to a low level when the low level is applied to the first bit line and the second bit line; and store data corresponding to the low level when a high level is applied to the first bit line and the second bit line.

According to embodiments of the present disclosure, the memory cell includes: a first pull-up transistor of the first inverter and a first pull-down transistor of the first inverter; a second pull-up transistor of the second inverter and a second pull-down transistor of the second inverter; a first transfer transistor connected between an output node of the first inverter and the first bit line; and a second transfer transistor connected between an output node of the second inverter and the second bit line; the memory cell is configured to satisfy at least one of: the first pull-up transistor and the second pull-up transistor have different thresholds with respect to each other; the first pull-down transistor and the second pull-down transistor have different thresholds with respect to each other; and the first transfer transistor and the second transfer transistor have different thresholds with respect to each other.

According to embodiments of the present disclosure, in a case that a threshold of the first pull-up transistor is higher than a threshold of the second pull-up transistor, a threshold of the first pull-down transistor is lower than or equal to a threshold of the second pull-down transistor.

According to embodiments of the present disclosure, the control circuit is configured to: generate an inverted signal of the first input signal as the processed first input signal and/or generate an inverted signal of the second input signal as the processed second input signal, according to the operation mode control signal.

According to embodiments of the present disclosure, the control circuit includes a first control sub-circuit and a second control sub-circuit; the first control sub-circuit includes: a first NOT gate, a second NOT gate, a first AND gate, a second AND gate and a first OR gate, where an input end of the first NOT gate is configured to receive the first input signal, an input end of the second NOT gate is configured to receive the operation mode control signal, a first input end of the first AND gate is configured to be connected to an output end of the first NOT gate, a second input end of the first AND gate is configured to receive the operation mode control signal, a first input end of the second AND gate is configured to be connected to an output end of the second NOT gate, a second input end of the second AND gate is configured to receive the first input signal, an input end of the first OR gate is configured to be connected to output ends of the first AND gate and the second AND gate, and an output end of the first OR gate is configured to be connected to the first bit line; the second control sub-circuit includes a third NOT gate, a fourth NOT gate, a third AND gate, a fourth AND gate and a second OR gate; an input end of the third NOT gate is configured to receive the second input signal, an input end of the fourth NOT gate is configured to receive the operation mode control signal, a first input end of the third AND gate is configured to be connected to an output end of the third NOT gate, a second input end of the third AND gate is configured to receive the operation mode control signal, a first input end of the fourth AND gate is configured to be connected to an output end of the fourth NOT gate, a second input end of the fourth AND gate is configured to receive the second input signal, an input end of the second OR gate is connected to output ends of the third AND gate and the fourth AND gate, and an output end of the second OR gate is configured to be connected to the second bit line.

According to embodiments of the present disclosure, the readout circuit includes a sensitive amplification module and a fifth NOT gate; an input end of the sensitive amplification module is connected to the memory cell through the first bit line and the second bit line, an output end of the sensitive amplification module is connected to a first output end of the computing-in-memory circuit and an input end of the fifth NOT gate, and an output end of the fifth NOT gate is connected to a second output end of the computing-in-memory circuit.

According to another aspect of the present disclosure, there is provided an SRAM memory device, including: an SRAM memory cell array including memory cells arranged in rows and columns, where each of the memory cells is connected between a corresponding first bit line and a corresponding second bit line and includes a first inverter and a second inverter cross-coupled with each other, and the first inverter and the second inverter have an asymmetric configuration with respect to each other; the memory cell is configured to store data according to a signal applied to the first bit line and a signal applied to the second bit line, and the asymmetric configuration causes that data stored in the memory cell has a data state or a data state that is in a reverse phase with the data state when a level corresponding to the same data state is applied to the first bit line and the second bit line.

According to embodiments of the present disclosure, the memory cell includes: a first pull-up transistor of the first inverter and a first pull-down transistor of the first inverter; a second pull-up transistor of the second inverter and a second pull-down transistor of the second inverter; a first transfer transistor connected between an output node of the first inverter and the first bit line; and a second transfer transistor connected between an output node of the second inverter and the second bit line; the memory cell is configured to satisfy at least one of: the first pull-up transistor and the second pull-up transistor have different thresholds with respect to each other; the first pull-down transistor and the second pull-down transistor have different thresholds with respect to each other; and the first transfer transistor and the second transfer transistor have different thresholds with respect to each other.

According to embodiments of the present disclosure, the SRAM memory cell array may realize a basic data reading and writing operation. Furthermore, the computing-in-memory circuit of embodiments of the present disclosure may complete various logical operations based on the memory cell having an asymmetric configuration through the control circuit. In addition, a logical operation function of the computing-in-memory circuit of embodiments of the present disclosure may be reconstructed through the control circuit, so that the computing-in-memory circuit of embodiments of the present disclosure may perform various logical operations. Moreover, the computing-in-memory circuit may directly write an operation result into the memory cell.

### BRIEF DESCRIPTION OF THE DRAWINGS

The above and other objectives, features, and advantages of the present disclosure will be clearer through the following descriptions of embodiments of the present disclosure with reference to accompanying drawings, in which:

FIG. 1 schematically shows a schematic diagram of a structural hierarchy of a computer storage system according to embodiments of the present disclosure.

FIG. 2 schematically shows a schematic diagram of a computing-in-memory circuit according to a first embodiment of the present disclosure.

FIG. 3 schematically shows a schematic diagram of a computing-in-memory circuit according to a second embodiment of the present disclosure.

FIG. 4 schematically shows a schematic diagram of a first control sub-circuit according to embodiments of the present disclosure.

FIG. 5 schematically shows a schematic diagram of a memory cell according to a first embodiment of the present disclosure.

FIG. 6 schematically shows a schematic diagram of a memory cell according to a second embodiment of the present disclosure.

FIG. 7 schematically shows a schematic diagram of a memory cell according to a third embodiment of the present disclosure.

FIG. 8 schematically shows a schematic diagram of a readout circuit according to embodiments of the present disclosure.

FIG. 9 schematically shows a schematic diagram of a computing-in-memory circuit according to a third embodiment of the present disclosure.

FIG. 10 schematically shows a schematic diagram of an SRAM memory device according to embodiments of the present disclosure.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In the following detailed descriptions, for the convenience of explanation, many specific details are set forth to provide a comprehensive understanding of embodiments of the present disclosure. However, it is obvious that one or more embodiments may be implemented without these specific details. In addition, in the following descriptions, descriptions of well-known structures and technologies are omitted to avoid unnecessarily obscuring the concept of the present disclosure.

Terms used herein are only intended to describe specific embodiments and are not intended to limit the present disclosure. Terms “include”, “comprise”, “contain”, etc. used herein indicate the presence of the described features, steps, operations and/or components, but do not exclude the presence or addition of one or more other features, steps, operations and/or components.

All terms (including technical and scientific terms) used herein have meanings generally understood by those skilled in the art, unless otherwise defined. It should be noted that the terms used herein should be interpreted as having the meaning consistent with the context of the present disclosure, and should not be interpreted in an idealized or overly rigid manner.

In a case that an expression similar to “at least one selected from A, B, or C” is used, the expression should generally be interpreted according to the meaning of the expression generally understood by those skilled in the art (e.g., “a system having at least one selected from A, B, or C” shall include, but is not limited to, a system having A alone, having B alone, having C alone, having A and B, having A and C, having B and C, and/or having A, B and C, etc.).

FIG. 1 schematically shows a schematic diagram of a hierarchical structure of a computer storage system according to embodiments of the present disclosure.

As shown in FIG. 1, as a process improvement gap between a processor and a memory widens, and a gap between a processing speed of a memory and a processing speed of a processor under a Von Neumann architecture increases continually, a problem of memory access power consumption wall is becoming increasingly prominent. For example, the hierarchical structure of the computer storage system may include a register, an on-chip first-level cache, an on-chip second-level cache, a main memory, a local auxiliary memory and a remote auxiliary memory from top to bottom. For example, the on-chip first-level cache may include SRAM (Static Random-Access Memory), etc. The on-chip second-level cache may include SRAM, etc. The main memory may include DRAM (Dynamic Random Access Memory), etc. The local auxiliary storage may include HD (Hard Disk), CD, etc. The remote auxiliary storage may include a web server, a local network, a distributed file system, etc. The layers shown in FIG. 1 may have a faster processing speed, a more expensive device and a smaller capacity from bottom to top.

Based on this, the inventor found that the problem of storage wall and/or power consumption wall may be solved at least partially through a computing-in-memory architecture. As the closest memory to CPU (Central Processing Unit), and an SRAM-based computing-in-memory technology has advantages of a fast reading and writing speed, a low power consumption, a strong reliability, a high scalability, etc., and is expected to become a mainstream intelligent computing architecture of the new generation.

In view of this, the present disclosure provides a computing-in-memory circuit, including: an SRAM memory cell array including at least one memory cell connected between a first bit line and a second bit line, where the memory cell includes a first inverter and a second inverter cross-coupled with each other, and the first inverter and the second inverter have an asymmetric configuration with respect to each other; a control circuit configured to: receive a first input signal, a second input signal and an operation mode control signal, process the first input signal and the second input signal according to the operation mode control signal, so as to obtain a processed first input signal and a processed second input signal, and apply the processed first input signal and the processed second input signal to the first bit line and the second bit line, respectively; and a readout circuit configured to read out data stored in the memory cell from the memory cell, where the memory cell is configured to store the data according to the processed first input signal and the processed second input signal applied to the first bit line and the second bit line, and the data corresponds to a result obtained by performing a logical operation indicated by the operation mode control signal on the first input signal and the second input signal.

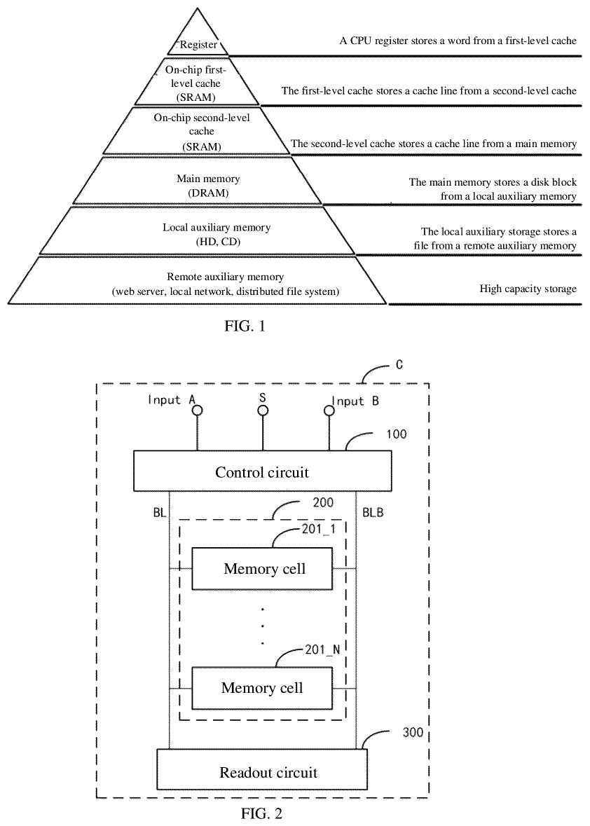

FIG. 2 schematically shows a schematic diagram of a computing-in-memory circuit according to a first embodiment of the present disclosure.

As shown in FIG. 2, a computing-in-memory circuit C of this embodiment may include: a control circuit 100, an SRAM memory cell array 200 and a readout circuit 300. The SRAM memory cell array 200 includes at least one memory cell 201 connected between a first bit line BL and a second bit line BLB. For example, memory cells 201_1, . . . , 201_N may be connected between the first bit line BL and the second bit line BLB, where N is an integer greater than 1.

According to embodiments of the present disclosure, the control circuit 100 is configured to: receive a first input signal Input A, a second input signal Input B and an operation mode control signal S, process the first input signal Input A and the second input signal Input B according to the operation mode control signal S, so as to obtain a processed first input signal Input A and a processed second input signal Input B, and apply the processed first input signal Input A and the processed second input signal Input B to the first bit line BL and the second bit line BLB, respectively.

According to embodiments of the present disclosure, the operation mode control signal S may be used to control an operation mode of the computing-in-memory circuit C, that is, to control a way in which the computing-in-memory circuit C performs a logical operation on the first input signal Input A and the second input signal Input B.

The operation mode of the computing-in-memory circuit C may include a standard SRAM mode and a logical operation mode.

In the standard SRAM mode, the computing-in-memory circuit C may operate as a normal SRAM. For example, in the case that the operation mode control signal S indicates the standard SRAM mode, the control circuit 100 may operate as a transfer gate, and the first input signal Input A and the second input signal Input B may be transmitted to the first bit line BL and the second bit line BLB, respectively. That is, a level of the processed first input signal Input A may be consistent with a level of the first input signal Input A, and a level of the processed second input signal Input B may be consistent with a level of the second input signal Input B. For the normal SRAM operation, inputs (corresponding to the first input signal Input A and the second input signal Input B, respectively) on the first bit line BL and the second bit line BLB may have levels that are in a reverse phase with each other. An addressed memory cell may store corresponding data (e.g., data corresponding to the level of the input on the first bit line BL) according to the inputs (with the levels that are in a reverse phase with each other) on the first bit line BL and the second bit line BLB.

In the case that the operation mode control signal S indicates the logical operation mode, the control circuit 100 may perform a logical processing, such as an inverse operation, on at least one of the first input signal Input A and the second input signal Input B, and transmit the first input signal Input A and the second input signal Input B (which are logically processed versions if logically processed) to the first bit line BL and the second bit line BLB, respectively. For example, the control circuit 100 may generate an inverted signal of the first input signal Input A as the processed first input signal Input A and/or an inverted signal of the second input signal Input B as the processed second input signal Input B according to the operation mode control signal S. The addressed memory cell may store corresponding data according to the inputs on the first bit line BL and the second bit line BLB. Since at least one of the first input signal Input A and the second input signal Input B has been logically processed in advance, the data finally stored in the memory cell may correspond to a result of the logical operation on both the first input signal Input A and the second input signal Input B. The logical operation may include, for example, an AND/NAND operation, an OR/NOR operation, etc. Accordingly, the logical operation mode control signal S may indicate an AND/NAND mode, an OR/NOR mode, etc. This will be further described in detail below.

For example, in the AND/NAND mode, the computing-in-memory circuit C may realize “AND operation” and/or “NAND operation” between the first input signal Input A and the second input signal Input B, and store a corresponding operation result in the memory cell. For another example, in the case that the computing-in-memory circuit C is in the OR/NOR mode, the computing-in-memory circuit C may realize “OR operation” and/or “NOR operation” between the first input signal Input A and the second input signal Input B, and store a corresponding operation result in the memory cell.

As described above, the control circuit 100 may preprocess the first input signal Input A and the second input signal Input B according to the operation mode control signal S, so that the data stored by the memory cell 201 in the memory cell array 200 according to the inputs on the first bit line BL and the second bit line BLB may correspond to a logical operation result between the first input signal Input A and the second input signal Input B, which is equivalent to directly writing the logical operation result into the memory cell 201, so that a writing cycle of data being written into the memory cell 201 may be reduced and a system delay may be reduced.

For example, the operation mode control signal S may include control signals respectively indicating the standard SRAM mode, the AND/NAND mode and the OR/NOR mode, etc., which are respectively used to control the computing-in-memory circuit so as to realize the standard SRAM mode, the AND/NAND mode and the OR/NOR mode, etc.

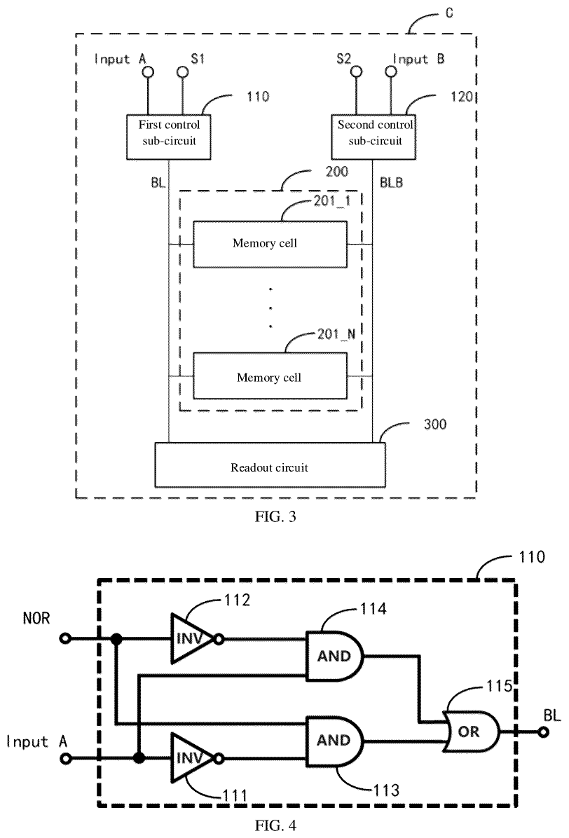

FIG. 3 schematically shows a schematic diagram of a computing-in-memory circuit according to a second embodiment of the present disclosure.

In this embodiment shown in FIG. 3, a first control sub-circuit 110 for the first input signal Input A and a second control sub-circuit 120 for the second input signal Input B are taken as examples to illustrate the implementation method of the control circuit. Those skilled in the art should understand that the implementation method of the control circuit 100 is not limited to this.

As shown in FIG. 3, the first control sub-circuit 110 is configured to receive the first input signal Input A and a first operation mode control sub-signal S1, and the second control sub-circuit 120 is configured to receive the second input signal Input B and a second operation mode control sub-signal S2. The first operation mode control sub-signal S1 and the second operation mode control sub-signal S2 may be derived from the operation mode control signal S received by the first control sub-circuit 110 or the operation mode control signal S received by the second control sub-circuit 120.

The first control sub-circuit 110 may be configured to selectively output the first input signal Input A or the inverted signal of the first input signal Input A to the first bit line BL according to the first operation mode control sub-signal S1. For example, in the case that the first operation mode control sub-signal S1 is at a low level (“0”), the first control sub-circuit 110 may input the first input signal Input A to the first bit line BL; in the case that the first operation mode control sub-signal S1 is at a high level (“1”), the first control sub-circuit 110 may input the inverted signal of the first input signal Input A to the first bit line BL. For example, as shown in FIG. 4, the first control sub-circuit 110 may include: a first NOT gate 111, a second NOT gate 112, a first AND gate 113, a second AND gate 114 and a first OR gate 115. An input end of the first NOT gate 111 is configured to receive the first input signal Input A, an input end of the second NOT gate 112 is configured to receive the first operation mode control sub-signal S1, a first input end of the first AND gate 113 is configured to be connected to an output end of the first NOT gate 111, a second input end of the first AND gate 113 is configured to receive the first operation mode control sub-signal S1, a first input end of the second AND gate 114 is configured to be connected to an output end of the second NOT gate 112, a second input end of the second AND gate 114 is configured to receive the first input signal Input A, an input end of the first OR gate 115 is configured to be connected to respective output ends of the first AND gate 113 and the second AND gate 114, and an output end of the first OR gate 115 is configured to be connected to the first bit line BL.

Similarly, the second control sub-circuit 120 may be configured to selectively output the second input signal Input B or the inverted signal of the second input signal Input B to the second bit line BLB according to the second operation mode control sub-signal S2. For example, in the case that the second operation mode control sub-signal S2 is at a low level (“0”), the second control sub-circuit 120 may input the second input signal Input B to the second bit line BLB; in the case that the first operation mode control sub-signal S2 is at a high level (“1”), the second control sub-circuit 120 may input the inverted signal of the second input signal Input B to the second bit line BLB. A circuit structure of the second control sub-circuit 120 may be consistent with a circuit structure of the first control sub-circuit 110. For example, the second control sub-circuit 120 may include: a third NOT gate, a fourth NOT gate, a third AND gate, a fourth AND gate and a second OR gate. An input end of the third NOT gate is configured to receive the second input signal Input B, an input end of the fourth NOT gate is configured to receive the second operation mode control sub-signal S2, a first input end of the third AND gate is configured to be connected with an output end of the third NOT gate, a second input end of the third AND gate is configured to receive the second operation mode control sub-signal S2, a first input end of the fourth AND gate is configured to be connected to an output end of the fourth NOT gate, a second input end of the fourth AND gate is configured to receive the second input signal Input B, an input end of the second OR gate is connected to respective output ends of the third AND gate and the fourth AND gate, and an output end of the second OR gate is configured to be connected to the second bit line BLB.

The first operation mode control sub-signal S1 and the second operation mode control sub-signal S2 may indicate corresponding logical operation modes, respectively. According to the circuit implementation method as described below, the first operation mode control sub-signal S1 (e.g., when it is “1”) may indicate an “OR operation result” and a “NOR operation result” between the first input signal Input A and the second input signal Input B. The second operation mode control sub-signal S2 (e.g., when it is “1”) may indicate an “AND operation result” and a “NAND operation result” between the first input signal Input A and the second input signal Input B.

For example, the first operation mode control sub-signal S1 and the second operation mode control sub-signal S2, both of which have a value of 0, jointly indicate the standard SRAM mode. For another example, the first operation mode control sub-signal S1 with a value of 0 and the second operation mode control sub-signal S2 with a value of 1 jointly indicate the AND/NAND mode. For another example, the first operation mode control sub-signal S1 with a value of 1 and the second operation mode control sub-signal S2 with a value of 0 jointly indicate the OR/NOR mode.

The operation mode control signal S may include two components to respectively indicate the first operation mode control sub-signal S1 and the second operation mode control sub-signal S2. Alternatively, the operation mode control signal S may include a single control word, such as a 2-bit control word (e.g., 00, 01, 10), from which the first operation mode control sub-signal S1 and the second operation mode control sub-signal S2 may be derived.

“AND” (correspondingly, “NAND”) and “OR (correspondingly, “NOR”) are basic logical operations. Here, they are taken as examples to describe embodiments. However, the present disclosure is not limited thereto. Based on the circuit implementation method, especially an implementation method of the memory cell 201, it is also feasible that the first operation mode control sub-signal (when it is “1”) indicates the OR/NOR mode and the second operation mode control sub-signal (when it is “1”) indicates the AND/NAND mode. Certainly, the first operation mode control sub-signal and the second operation mode control sub-signal may also indicate other logical operations.

Therefore, the memory cell 201 may store data according to the processed first input signal Input A (e.g., the first input signal Input A itself or its inverted signal) and the processed second input signal Input B (e.g., the second input signal Input B itself or its inverted signal) applied to the first bit line BL and the second bit line BLB, and the stored data corresponds to a result obtained by performing a logical operation indicated by the operation mode control signal S on the first input signal Input A and the second input signal Input B.

For example, the memory cell 201 includes a first inverter and a second inverter cross-coupled with each other, which may be connected between the first bit line BL and the second bit line BLB. Generally, the first inverter and the second inverter are kept in corresponding data states according to data (which are usually in a reverse phase with each other) on the first bit line BL and the second bit line BLB. According to embodiments, due to the preprocessing of the first input signal Input A and the second input signal Input B, data input to the first bit line BL and the second bit line BLB may be not in a reverse phase with each other, for example, they may have the same logical state (“1” or “0”). In order that the first inverter and the second inverter may also work in this case, the first inverter and the second inverter may have an asymmetric configuration with respect to each other. For example, both the first inverter and the second inverter include a P-type (pull-up) transistor and an N-type (pull-down) transistor. The asymmetric configuration may mean that the P-type transistor of the first inverter and the P-type transistor of the second inverter have different thresholds from each other. The asymmetric configuration may also mean that the N-type transistor of the first inverter and the N-type transistor of the second inverter have different thresholds from each other.

For example, the asymmetric configuration may cause that in the memory cell 201: when a level corresponding to a first data state is applied to the first bit line BL and a level corresponding to a second data state is applied to the second bit line BLB, the data stored in the memory cell 201 has the first data state, where the second data state is in a reverse phase with the first data state (e.g., in the standard SRAM mode). When a level corresponding to a same data state is applied to the first bit line BL and the second bit line BLB, the data stored in the memory cell 201 has the data state or a data state that is in a reverse phase with the data state. For example, the asymmetric configuration may cause the memory cell 201 to: when a low level is applied to the first bit line BL and the second bit line BLB, store data corresponding to the low level; and when a high level is applied to the first bit line BL and the second bit line BLB, store data corresponding to the high level (e.g., in the logical operation mode).

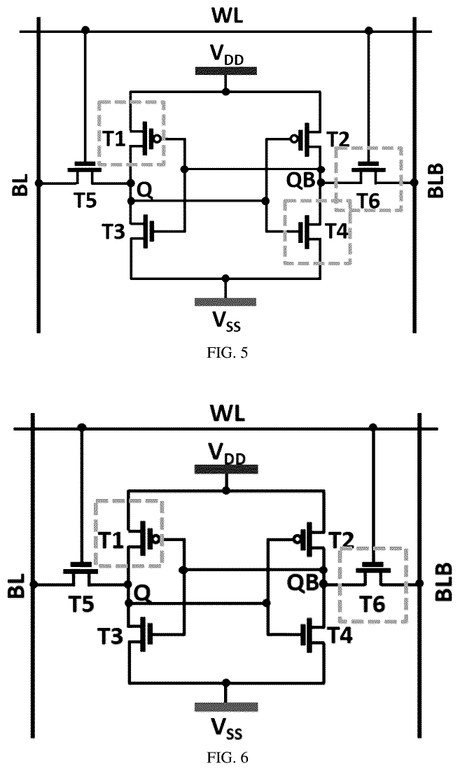

FIG. 5 schematically shows a schematic diagram of the memory cell 201 according to a first embodiment of the present disclosure.

As shown in FIG. 5, the memory cell 201 includes: a first inverter including a first pull-up transistor T1 and a first pull-down transistor T3; and a second inverter including a second pull-up transistor T2 and a second pull-down transistor T4. The first inverter and the second inverter are connected between a power supply voltage V_{DD} and a ground voltage V_{SS}, respectively. A first transfer transistor T5 is connected between an output node Q of the first inverter and the first bit line BL, and a second transfer transistor T6 is connected between an output node QB of the second inverter and the second bit line BLB. The output node Q of the first inverter is connected to an input (a gate of both the second pull-up transistor T2 and the second pull-down transistor T4) of the second inverter, and the output node QB of the second inverter is connected to an input (a gate of both the first pull-up transistor T1 and the first pull-down transistor T3) of the first inverter. For example, the first pull-up transistor T1 and the second pull-up transistor T2 are both P-type transistors. The first pull-down transistor T3, the second pull-down transistor T4, the first transfer transistor T5 and the second transfer transistor T6 are all N-type transistors. The first transfer transistor T5 and the second transfer transistor T6 may be controlled by a signal from a word line WL to turn on or off, which will not be repeated in detail here.

The memory cell 201 may be configured to satisfy at least one of: the first pull-up transistor T1 and the second pull-up transistor T2 have different thresholds with respect to each other; the first pull-down transistor T3 and the second pull-down transistor T4 have different thresholds with respect to each other; and the first transfer transistor T5 and the second transfer transistor T6 have different thresholds with respect to each other. The threshold refers to a gate voltage threshold.

According to embodiments of the present disclosure, in the case that the threshold of the first pull-up transistor is higher than that of the second pull-up transistor T2, the threshold of the first pull-down transistor T3 may be lower than or equal to the threshold of the second pull-down transistor T4.

For example, the threshold of the first pull-up transistor T1 is higher than the threshold of the second pull-up transistor T2, and the threshold of the first pull-down transistor T3 is lower than the threshold of the second pull-down transistor T4. In FIG. 5, the transistors with relatively high thresholds are marked with dashed boxes. The configuration may make the output node Q of the first inverter more easily connected to a level of the ground end VSS, that is, “0”, and the output node QB of the second inverter more easily connected to the level of the voltage input end VDD, that is, “1”. Therefore, when the first bit line BL and the second bit line BLB have the same level, respective levels of the output node Q of the first inverter and the output node QB of the second inverter will be pulled to levels where the output node Q of the first inverter and the output node QB of the second inverter are easily pulled. Therefore, when BL=BLB=0 or BL=BLB=1, Q=0 and QB=1.

In order to improve a performance of the memory cell 201, the threshold of the first transfer transistor T5 may be lower than the threshold of the second transfer transistor T6, which will not be limited to this. In some embodiments, the threshold of the first transfer transistor T5 may be same as the threshold of the second transfer transistor T6.

Based on this, since the two inverters constituting the memory cell 201 have the asymmetric configuration, an input signal and an output signal of the memory cell 201 are shown in Table 1 below.

TABLE 1

| Input signal | | Output signal | |
|---|---|---|---|
| BL | BLB | Q | QB |
| 0 | 0 | 0 | 1 |
| | 1 | 0 | 1 |
| 1 | 0 | 1 | 0 |
| | 1 | 0 | 1 |

As may be seen from Table 1, when levels of the first bit line BL and the second bit line BLB are both 0 or 1, a level of the output node Q of the first inverter is 0 and a level of the output node QB of the second inverter is 1.

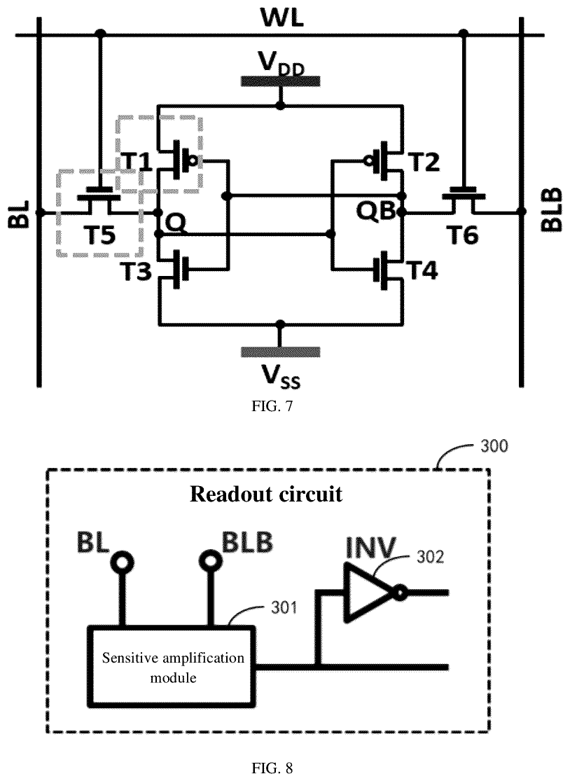

It should be noted that the asymmetric configuration in embodiments of the present disclosure is not limited to this embodiment shown in FIG. 5. For example, as shown in FIG. 6, in some embodiments, the threshold of the first pull-up transistor T1 may be higher than the threshold of the second pull-up transistor T2, the threshold of the first pull-down transistor T3 may be equal to the threshold of the second pull-down transistor T4, and the threshold of the first transfer transistor T5 may be lower than the threshold of the second transfer transistor T6. For another example, as shown in FIG. 7, in some embodiments, the threshold of the first pull-up transistor T1 may be higher than the threshold of the second pull-up transistor T2, the threshold of the first pull-down transistor T3 may be equal to the threshold of the second pull-down transistor T4, and the threshold of the first transfer transistor T5 may be higher than the threshold of the second transfer transistor T6. Similarly, in FIG. 6 and FIG. 7, the transistors with relatively high thresholds are marked with dashed boxes.

FIG. 8 schematically shows a schematic diagram of the readout circuit 300 according to embodiments of the present disclosure.

As shown in FIG. 8, the readout circuit 300 is configured to read out data stored in the memory cell 201 from the memory cell 201. In order to realize more types of logical operations, the readout circuit 300 may also invert the data read from the memory cell 201. For example, the readout circuit 300 may include a sensitive amplification module 301 and a fifth NOT gate 302. An input end of the sensitive amplification module 301 is connected to the memory cell 201 through the first bit line BL and the second bit line BLB, an output end of the sensitive amplification module 301 is connected to a first output end of the computing-in-memory circuit C and an input end of the fifth NOT gate 302, and an output end of the fifth NOT gate 302 is connected to a second output end of the computing-in-memory circuit C.

The sensitive amplification module 301 reads out the data (e.g., an inverted signal corresponding to a data state at the output node Q of the first inverter or a data state at the output node QB of the second inverter) stored in the memory cell 201 according to data states (in a read-out mode, the two data states are in a reverse phase with each other) on the first bit line BL and the second bit line BLB. Through the fifth NOT gate 302, an inverted signal of the data may be obtained. For example, when the data stored in the memory cell 201 corresponds to an AND result of the first input signal Input A and the second input signal Input B, an output of the fifth NOT gate 302 may correspond to a NAND result. Alternatively, when the data stored in the memory cell 201 corresponds to an OR result of the first input signal Input A and the second input signal Input B, the output of the fifth NOT gate 302 may correspond to a NOR result.

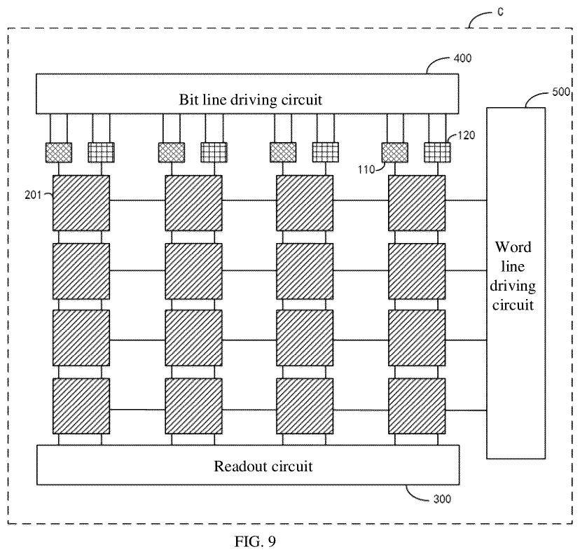

FIG. 9 schematically shows a schematic diagram of a computing-in-memory circuit according to a third embodiment of the present disclosure.

As shown in FIG. 9, the SRAM memory cell array 200 in embodiments of the present disclosure includes memory cells 201 arranged in rows and columns. The memory and calculation integrated circuit C in embodiments of the present disclosure may further include a bit line driving circuit 400 and a word line driving circuit 500. Each column of memory cells 201 may be connected to the bit line driving circuit 400 through corresponding bit lines (e.g., the first bit line BL and the second bit line BLB), and each row of memory cells 201 may be connected to the word line driving circuit 500 through corresponding word lines WL. It should be noted that, for the convenience of representation, the same device is shown with the same filling pattern in FIG. 11.

The bit line driving circuit 400 may be configured to receive a signal from a host computer or other devices, and a source of the signal will not be limited in the present disclosure. The signal received by the bit line driving circuit 400 may include a (column) address of the target memory cell 201, data (e.g., the first input signal Input A and the second input signal Input B) to be stored or logically operated, and the operation mode control signal S. The bit line driving circuit 400 may include an address decoder. The address decoder may be configured to decode the (column) address included in the signal received by the bit line driving circuit 400, determine a column in which the target memory cell 201 is located, and transmit the data and the operation mode control signal to the first control sub-circuit 110 and the second control sub-circuit 120 corresponding to the column.

The first control sub-circuit 110 and the second control sub-circuit 120 corresponding to the column may process the first input signal Input A and the second input signal Input B according to the operation mode control signal S, so as to obtain the processed first input signal Input A and the processed second input signal Input B, and apply the processed first input signal Input A to the first bit line BL and the processed second input signal Input B to the second bit line BLB. For the first control sub-circuit 110 and the second control sub-circuit 120 connected to the memory cells 201 in other columns, input ends of the first control sub-circuit 110 and the second control sub-circuit 120 for receiving the operation mode control signal S may both be kept at “0”.

Similarly, the word line driving circuit 500 may also be configured to receive a signal from an upper computer or other devices, and a source of the signal will not be limited in the present disclosure. The signal received by the word line driving circuit 500 may include a (row) address of the target memory cell 201. The word line driving circuit 500 may include an address decoder. The address decoder may be configured to decode the (row) address included in the signal received by the word line driving circuit 500, and determine a row in which the target memory cell 201 is located. The word line driving circuit 500 may activate the row, for example, by applying a high level to bit lines connected to the memory cells 201 of the row. Then, the first transfer transistor T5 and the second transfer transistor T6 of the memory cells 201 of the row may be turned on, so that the processed first input signal Input A and the processed second input signal Input B are written into the target memory cell 201 through the first bit line BL and the second bit line BLB of the corresponding column, respectively.

As described above, the data stored in the target memory cell 201 may correspond to a logical operation result of the first input signal Input A and the second input signal Input B. The readout circuit 300 may read out and output the data stored in the target memory cell 201 through the first bit line BL and the second bit line BLB, thereby realizing the function of the computing-in-memory circuit C of the present disclosure.

For example, when the first operation mode control sub-signal S1 is 0 and the first operation mode control sub-signal S2 is 1, the computing-in-memory circuit C enters the AND/NAND mode. When the first input signal Input A is 1 and the second input signal Input B is 1, the level of the first bit line BL is 1 and the level of the second bit line BLB is 0, and data 1 is written to the output node Q of the first inverter of the SRAM cell. Similarly, results in Table 2 below may be obtained, that is, an “AND operation result” of the first input signal Input A and the second input signal Input B is written into the memory cells 201 located in a target column and a target row. The “AND operation result” and a “NAND operation result” may be simultaneously output by the readout circuit 300.

TABLE 2

| Input signal | | Memory cell | | | Output signal | |
|---|---|---|---|---|---|---|
| Input A | Input B | BL | BLB | Q | Out1 (AND) | Out2 (NAND) |
| 0 | 0 | 0 | 1 | 0 | 0 | 1 |
| 0 | 1 | 0 | 0 | 0 | 0 | 1 |
| 1 | 0 | 1 | 1 | 0 | 0 | 1 |
| 1 | 1 | 1 | 0 | 1 | 1 | 0 |

When the first operation mode control sub-signal S1 is 1 and the first operation mode control sub-signal S2 is 0, the storage-operation integrated circuit C enters the OR/NOR mode. When the first input signal Input A is 0 and the second input signal Input B is 0, the level of the first bit line BL is 1 and the level of the second bit line BLB is 0, and data 1 is written to the output node Q of the first inverter of the SRAM cell. Similarly, results in Table 3 below may be obtained, that is, a “NOR operation result” of the first input signal Input A and the second input signal An “OR operation result” and the “NOR operation result” may be simultaneously output by the readout circuit 300.

TABLE 3

| Input signal | | SRAM cell | | | Output signal | |
|---|---|---|---|---|---|---|
| Input A | Input B | BL | BLB | Q | Out1 (NOR) | Out2 (OR) |
| 0 | 0 | 1 | 0 | 1 | 1 | 0 |
| 0 | 1 | 1 | 1 | 0 | 0 | 1 |
| 1 | 0 | 0 | 0 | 0 | 0 | 1 |
| 1 | 1 | 0 | 1 | 0 | 0 | 1 |

According to embodiments of the present disclosure, the SRAM memory cell array 200 may realize a basic data reading and writing operation. Furthermore, the computing-in-memory circuit C of embodiments of the present disclosure may complete various logical operations based on the memory cell 201 with the asymmetric configuration through the control circuit 100. In addition, the logical operation function of the computing-in-memory circuit C of embodiments of the present disclosure may be reconstructed by the control circuit 100, so that the computing-in-memory circuit C of embodiments of the present disclosure may perform various logical operations. Moreover, the computing-in-memory circuit C may directly write an operation result into the memory cell 201.

Through the computing-in-memory circuit C of embodiments of the present disclosure, a writing cycle of data being written into the memory cell may be saved, a system delay may be reduced, a data operation rate may be improved, and a data operation power consumption of the system may be reduced, thereby alleviating the problems of storage wall and power consumption wall.

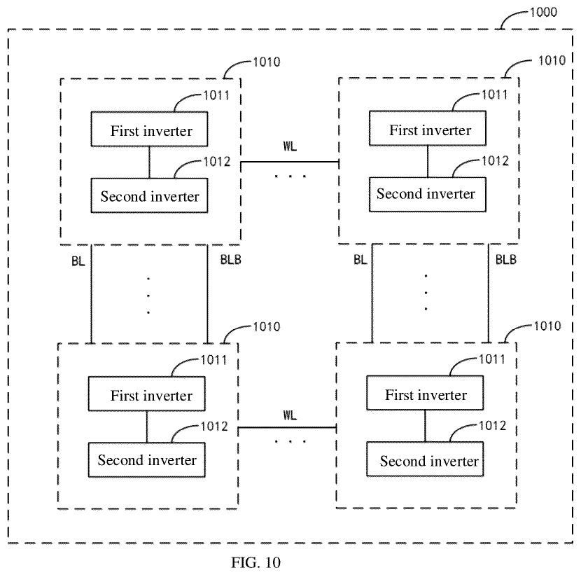

FIG. 10 schematically shows a schematic diagram of an SRAM memory device according to embodiments of the present disclosure.

As shown in FIG. 10, the SRAM memory device of the embodiments may include an SRAM memory cell array 1000 including memory cells 1010 arranged in rows and columns. Each memory cell 1010 is connected between a corresponding first bit line BL and a corresponding second bit line BLB and includes a first inverter 1011 and a second inverter 1012 cross-coupled with each other, and the first inverter 1011 and the second inverter 1012 have an asymmetric configuration with respect to each other. The memory cell 1010 stores data according to a signal applied to the first bit line BL and a signal applied to the second bit line BLB, and the asymmetric configuration causes that when a level corresponding to a same data state is applied to the first bit line BL and the second bit line BLB, the data stored in the memory cell 1010 has the data state or a data state that is in a reverse phase with the data state.

According to embodiments of the present disclosure, each row of memory cells 1010 are connected through a corresponding word line WL.

Various functions and structures of the memory cells in the embodiments are the same as or similar to the functions, structures, and connection methods of the memory cells in the embodiments of FIG. 2 to FIG. 9, which will not be repeated here. It should be noted that information, such as the number of memory cells, etc. in the accompanying drawings of the present disclosure is exemplary, which will not be limited in the present disclosure.

Embodiment of the present disclosure have been described in detail with reference to the accompany drawings. It should be noted that the implementation methods not shown or described in the accompany drawings or the text of the specification are all known to those skilled in the art, and have not been described in detail. In addition, the above definitions of various elements and methods are not limited to the specific structures, shapes or ways mentioned in the embodiments, and those skilled in the art may simply change or replace them.

Throughout the accompanying drawings, the same elements are indicated by the same or similar reference numerals. When it may cause confusion in the understanding of the present disclosure, conventional structures or configurations may be omitted.

In addition, the shapes and dimensions of components in the drawings do not necessarily reflect actual sizes and/or ratios, but merely illustrate the content of embodiments of the present disclosure. Furthermore, in the claims, any reference signs in parentheses should not be construed as limiting the claims.

Unless known to the contrary, the numerical parameters in the specification and the appended claims are approximations and may be changed according to the desired characteristics obtained through the present disclosure. In particular, all numbers used in the specification and the claims to indicate composition contents, reaction conditions, etc. should be understood as being modified in all cases by the term “about”. Furthermore, the word “containing”, “including” or “comprising” does not exclude the presence of elements or steps not listed in the claims. The word “a” or “an” preceding an element does not exclude the presence of a plurality of the elements.

Ordinal numbers such as “first,” “second,” “third,” etc., used in the description and claims are only to modify corresponding elements, which does not mean any ordinal numbers of the elements, or any order of an element and another element, or any order in a manufacturing method. The ordinal numbers are used only to clearly distinguish an element having a name from another element having the same name.

The algorithms and displays provided herein are not inherently related to any particular computer, virtual system or other devices. Various general-purpose systems may also be used with the teachings based herein. According to the above-mentioned descriptions, the structure required to construct such a system is obvious. In addition, the present disclosure is not directed to any particular programming language. It should be understood that the content of the present disclosure described herein may be implemented using various programming languages, and the description of specific languages above is to disclose the best implementation method of the present disclosure.

The present disclosure may be implemented by means of hardware containing several different elements and by means of a suitably programmed computer. Various component embodiments of the present disclosure may be implemented in hardware, or in software modules running on one or more processors, or in a combination thereof. It should be understood by those skilled in the art that a microprocessor or a digital signal processor (DSP) may be used in practice to realize some or all functions of some or all components in related devices according to embodiments of the present disclosure. The present disclosure may also be implemented as a device or apparatus program (e.g., a computer program and a computer program product) for performing part or all of the methods described herein. Such a program for implementing the present disclosure may be stored on a computer-readable medium, or may be in the form of one or more signals.

Those skilled in the art may understand that the modules in the device in the embodiments may be adaptively changed and set in one or more devices different from the embodiments. The modules or units or components in the embodiments may be combined into one module or unit or component, and additionally they may be divided into a plurality of sub-modules or sub-units or sub-assemblies. Except that at least some of such features and/or processes or units are mutually exclusive, all features disclosed in the specification (including appended claims, abstract and accompanying drawings) and all processes or units of any method or equipment so disclosed may be combined in any combination. Unless explicitly stated otherwise, each feature disclosed in the specification (including the appended claims, abstract and accompanying drawings) may be replaced by alternative features that serve the same, equivalent or similar purpose. Moreover, in the unit claim listing several apparatuses, several of these apparatuses may be specifically embodied by one and the same item of hardware.

Similarly, it should be understood that, in order to simplify the present disclosure and help to understand one or more aspects of the present disclosure, in the above-mentioned descriptions of exemplary embodiments of the present disclosure, various features of the present disclosure are sometimes grouped together into a single embodiment, figure, or description thereof. However, the method of the present disclosure should not be interpreted as reflecting the intention that the claimed disclosure requires more features than those explicitly recited in each claim. Rather, as reflected in the following claims, the disclosure aspects lie in less than all features of a single embodiment disclosed previously. Therefore, the claims following the specific embodiments are hereby explicitly incorporated into the specific embodiment, where each claim serves as a separate embodiment of the present disclosure.

The above-mentioned specific embodiments have described in detail the objectives, technical solutions and advantages of the present disclosure. It should be noted that the above are only specific embodiments of the present disclosure and are not intended to limit the present disclosure. Any modifications, equivalent substitutions, improvements, and the like made within the spirit and scope of the present disclosure shall be included in the scope of protection of the present disclosure.

What is claimed is:

1. A computing-in-memory circuit, comprising:
an SRAM memory cell array comprising at least one memory cell connected between a first bit line and a second bit line, wherein the memory cell comprises a first inverter and a second inverter cross-coupled with each other, and the first inverter and the second inverter have an asymmetric configuration with respect to each other;
a control circuit configured to:
receive a first input signal, a second input signal and an operation mode control signal,
process the first input signal and the second input signal according to the operation mode control signal, so as to obtain a processed first input signal and a processed second input signal, and
apply the processed first input signal and the processed second input signal to the first bit line and the second bit line, respectively; and
a readout circuit configured to read out data stored in the memory cell from the memory cell,
wherein the memory cell is configured to store the data according to the processed first input signal and the processed second input signal applied to the first bit line and the second bit line, and the data corresponds to a result obtained by performing a logical operation indicated by the operation mode control signal on the first input signal and the second input signal.

2. The computing-in-memory circuit according to claim 1, wherein the asymmetric configuration causes the memory cell to:
store data having a first data state when a level corresponding to the first data state is applied to the first bit line and a level corresponding to a second data state is applied to the second bit line, wherein the second data state is in a reverse phase with the first data state; and
store data having a data state or a data state that is in a reverse phase with the data state when a level corresponding to the same data state is applied to the first bit line and the second bit line.

3. The computing-in-memory circuit according to claim 2, wherein the asymmetric configuration causes the memory cell to:
store data corresponding to a low level when the low level is applied to the first bit line and the second bit line; and
store data corresponding to the low level when a high level is applied to the first bit line and the second bit line.

4. The computing-in-memory circuit according to claim 1, wherein the memory cell comprises:
a first pull-up transistor of the first inverter and a first pull-down transistor of the first inverter;
a second pull-up transistor of the second inverter and a second pull-down transistor of the second inverter;
a first transfer transistor connected between an output node of the first inverter and the first bit line; and
a second transfer transistor connected between an output node of the second inverter and the second bit line,
wherein the memory cell is configured to satisfy at least one of:
the first pull-up transistor and the second pull-up transistor have different thresholds with respect to each other;
the first pull-down transistor and the second pull-down transistor have different thresholds with respect to each other; and
the first transfer transistor and the second transfer transistor have different thresholds with respect to each other.

5. The computing-in-memory circuit according to claim 4, wherein in a case that a threshold of the first pull-up transistor is higher than a threshold of the second pull-up transistor, a threshold of the first pull-down transistor is lower than or equal to a threshold of the second pull-down transistor.

6. The computing-in-memory circuit according to claim 1, wherein the control circuit is configured to: generate an inverted signal of the first input signal as the processed first input signal and/or generate an inverted signal of the second input signal as the processed second input signal, according to the operation mode control signal.

7. The computing-in-memory circuit according to claim 6, wherein the control circuit comprises a first control sub-circuit and a second control sub-circuit;
the first control sub-circuit comprises: a first NOT gate, a second NOT gate, a first AND gate, a second AND gate and a first OR gate, wherein an input end of the first NOT gate is configured to receive the first input signal, an input end of the second NOT gate is configured to receive the operation mode control signal, a first input end of the first AND gate is configured to be connected to an output end of the first NOT gate, a second input end of the first AND gate is configured to receive the operation mode control signal, a first input end of the second AND gate is configured to be connected to an output end of the second NOT gate, a second input end of the second AND gate is configured to receive the first input signal, an input end of the first OR gate is configured to be connected to output ends of the first AND gate and the second AND gate, and an output end of the first OR gate is configured to be connected to the first bit line;
the second control sub-circuit comprises: a third NOT gate, a fourth NOT gate, a third AND gate, a fourth AND gate and a second OR gate,
wherein an input end of the third NOT gate is configured to receive the second input signal, an input end of the fourth NOT gate is configured to receive the operation mode control signal, a first input end of the third AND gate is configured to be connected to an output end of the third NOT gate, a second input end of the third AND gate is configured to receive the operation mode control signal, a first input end of the fourth AND gate is configured to be connected to an output end of the fourth NOT gate, a second input end of the fourth AND gate is configured to receive the second input signal, an input end of the second OR gate is connected to output ends of the third AND gate and the fourth AND gate, and an output end of the second OR gate is configured to be connected to the second bit line.

8. The computing-in-memory circuit according to claim 1, wherein the readout circuit comprises a sensitive amplification module and a fifth NOT gate;
an input end of the sensitive amplification module is connected to the memory cell through the first bit line and the second bit line, an output end of the sensitive amplification module is connected to a first output end of the computing-in-memory circuit and an input end of the fifth NOT gate, and an output end of the fifth NOT gate is connected to a second output end of the computing-in-memory circuit.

9. An SRAM memory device, comprising:
an SRAM memory cell array comprising memory cells arranged in rows and columns, wherein each of the memory cells is connected between a corresponding first bit line and a corresponding second bit line and comprises a first inverter and a second inverter cross-coupled with each other, and the first inverter and the second inverter have an asymmetric configuration with respect to each other,
wherein the memory cell is configured to store data according to a signal applied to the first bit line and a signal applied to the second bit line, and the asymmetric configuration causes that data stored in the memory cell has a data state or a data state that is in a reverse phase with the data state when a level corresponding to the same data state is applied to the first bit line and the second bit line.

10. The SRAM memory device according to claim 9, wherein the memory cell comprises:
a first pull-up transistor of the first inverter and a first pull-down transistor of the first inverter;
a second pull-up transistor of the second inverter and a second pull-down transistor of the second inverter;
a first transfer transistor connected between an output node of the first inverter and the first bit line; and
a second transfer transistor connected between an output node of the second inverter and the second bit line,
wherein the memory cell is configured to satisfy at least one of:
the first pull-up transistor and the second pull-up transistor have different thresholds with respect to each other;
the first pull-down transistor and the second pull-down transistor have different thresholds with respect to each other; and
the first transfer transistor and the second transfer transistor have different thresholds with respect to each other.
